(19) United States
(12) Patent Application Publication
(10) Pub. No.: US 2010/0227478 A1
(43) Pub. Date: Sep. 9, 2010

(54) SUBSTRATE PROCESSING APPARATUS AND METHOD OF MANUFACTURING SEMICONDUCTOR

(75) Inventor: Koichiro HARADA, Toyama-shi (JP)

Correspondence Address: BRUNDIDGE & STANGER, P.C., 2318 MILL ROAD, SUITE 1020, ALEXANDRIA, VA, 22314, US

(73) Assignee: HITACHI-KOKUSAI ELECTRIC INC., Tokyo (JP)

(21) Appl. No.: 12/716,837

(22) Filed: Mar. 3, 2010

(30) Foreign Application Priority Data
Mar. 4, 2009 (JP) 2009-050607
Feb. 4, 2010 (JP) 2010-022974

(51) Int. Cl. H01L 21/302; C23F 1/08; C23C 16/00; H01L 21/306

(52) U.S. Cl. 438/735; 156/345.29; 118/725; 438/758; 257/E21.219; 257/E21.214

(57) ABSTRACT

Provided are a substrate processing apparatus and a method of manufacturing a semiconductor device which can prevent a sealing member from being deteriorated due to a thermal radiation from a heater. The substrate processing apparatus includes a processing container, a substrate stage installed in the processing container, on which a substrate is placed, a heater installed in the substrate stage and configured to heat the substrate, a thermal radiation attenuator adjacent to the processing container, and a gas supply pipe connected to a gas inlet part with a sealing member interposed therebetween and configured to supply a processing gas to an inside of the processing container, wherein the thermal radiation attenuator is installed on a line connecting the heater and the sealing member.

### CROSS-REFERENCE TO RELATED PATENT APPLICATION

This U.S. non-provisional patent application claims priority under 35 U.S.C. §119 of Japanese Patent Application Nos. 2009-050607, filed on Mar. 4, 2009, and 2010-022974, filed on Feb. 4, 2009, in the Japanese Patent Office, the entire contents of which are hereby incorporated by reference.

### BACKGROUND OF THE INVENTION

1. Field of the Invention

The present invention relates to a substrate processing apparatus configured to process a substrate and a method of manufacturing a semiconductor device.

2. Description of the Prior Art

Recently, when manufacturing a semiconductor device such as a dynamic random access memory (DRAM) or an integrated circuit (IC), a substrate processing apparatus, which includes a processing container, a substrate stage installed in the processing container and on which a substrate is placed, a heater installed in the substrate stage and configured to heat the substrate, and a gas supply pipe connected to the processing container with a sealing member such as an O-ring interposed therebetween and configured to supply a processing gas to an inside of the processing container, is used. While the substrate is heated by the heater, as a processing gas is supplied to the inside of the processing container, for example, a substrate processing such as a film-forming processing is performed.

However, when the substrate is heated by the heater, the sealing member such as an O-ring installed between the processing container and the gas supply pipe is heated by a thermal radiation from the heater to cause deterioration such as discoloration, so that air-tightness in the processing container may be lowered. Also, since the sealing member such as an O-ring is melted by heat, the inside of the processing container or the substrate may be contaminated.

### SUMMARY OF THE INVENTION

An object of the present invention is to provide a substrate processing apparatus and a method of manufacturing a semiconductor device which can prevent a sealing member from being deteriorated due to a thermal radiation from a heater.

According to an aspect of the present invention, there is provided a substrate processing apparatus including: a processing container; a substrate stage installed in the processing container, on which a substrate is placed; a heater installed in the substrate stage and configured to heat the substrate; a thermal radiation attenuator adjacent to the processing container; and a gas supply pipe connected to a gas inlet part with a sealing member interposed therebetween and configured to supply a processing gas to an inside of the processing container, wherein the thermal radiation attenuator is installed on a line connecting the heater and the sealing member.

According to another aspect of the present invention, there is provided a method of manufacturing a semiconductor device including: loading a substrate to a processing container and placing the substrate on a substrate stage; heating the substrate by using a heater installed in the substrate stage; processing the substrate by supplying a processing gas to the processing container via a thermal radiation attenuator, which is connected to a processing gas supply pipe with a sealing member disposed therebetween and is installed on a line the substrate stage and the sealing member; and unloading the substrate from a processing chamber.

### BRIEF DESCRIPTION OF THE DRAWINGS

FIG. 1 is a schematic view of a substrate processing apparatus according to a first embodiment of the present invention.

FIG. 2 is a schematic view illustrating that a thermal radiation toward an O-ring is shielded by a gas inlet according to the first embodiment of the present invention.

FIG. 3 is a schematic view illustrating that a thermal radiation toward an O-ring is shielded by a gas inlet according to a second embodiment of the present invention.

FIG. 4 is a schematic view illustrating that a thermal radiation toward an O-ring is shielded by a gas inlet according to a third embodiment of the present invention.

FIG. 5 is a schematic view illustrating that a thermal radiation toward an O-ring is shielded by a gas inlet according to a fourth embodiment of the present invention.

FIG. 6 is a schematic view illustrating that a thermal radiation toward an O-ring is shielded by a gas inlet according to a fifth embodiment of the present invention.

FIG. 7 is a perspective view of a gas inlet according to a fifth embodiment of the present invention.

FIG. 8 is a schematic view illustrating a gas inlet according to another embodiment of the present invention.

FIG. 9 is a schematic view illustrating a gas inlet according to still another embodiment of the present invention.

FIG. 10 is a schematic view of a conventional substrate processing apparatus.

### DETAILED DESCRIPTION OF THE PREFERRED EMBODIMENTS

### First Embodiment of the Present Invention

(1) Constitution of Substrate Processing Apparatus

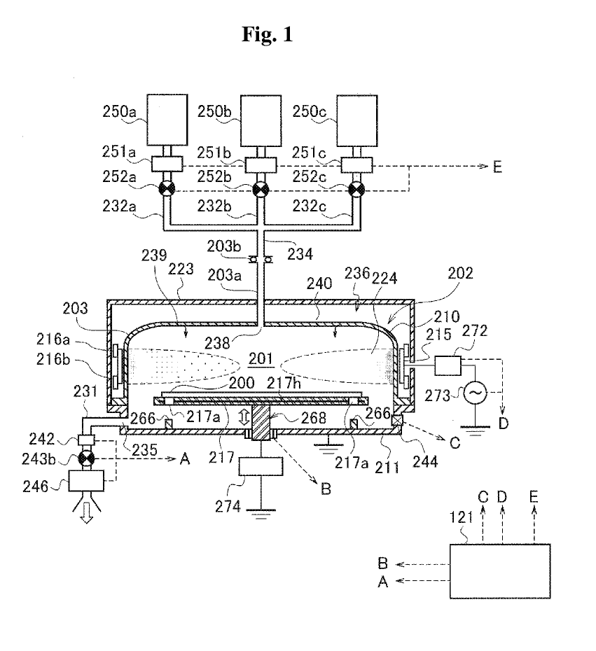

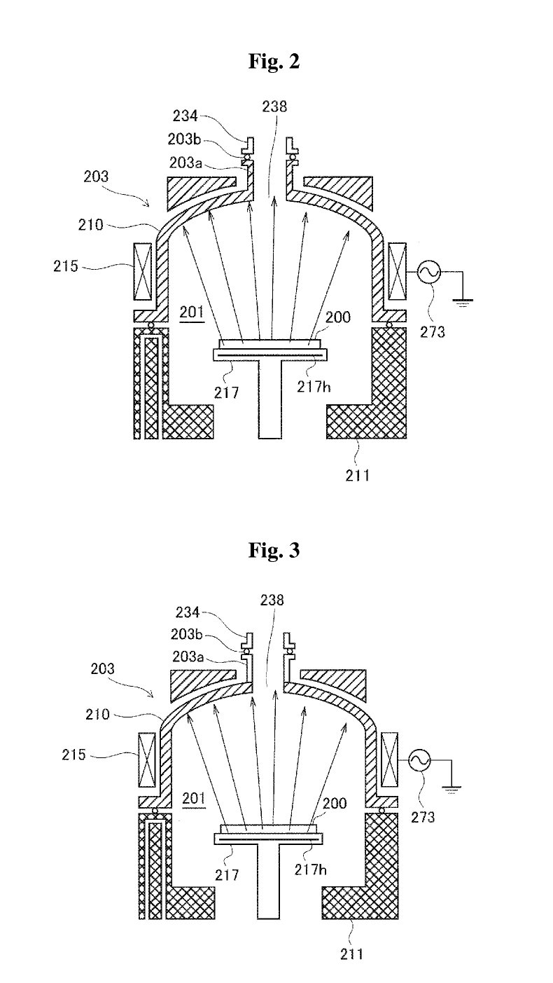

Hereinafter, constitution of a substrate processing apparatus relevant to a first embodiment of the present invention will be described. FIG. 1 is a schematic sectional view of a substrate processing apparatus, relevant to a first embodiment of the present invention. FIG. 2 is a schematic view illustrating that a thermal radiation directed toward an O-ring is shielded by a gas inlet, relevant to the first embodiment of the present invention.

The substrate processing apparatus relevant to the current embodiment is configured by a modified magnetron typed plasma (MMT) apparatus plasma-processing a substrate using a modified magnetron typed plasma source. The MMT apparatus is an apparatus configured to generate high density plasma by an electric field and a magnetic field, and is configured to generate high density plasma by allowing electrons emitted from a discharge electrode to perform a cycloid movement while drifting, increasing the generation rate of ions due to long-life span of plasma. By loading the substrate into a processing chamber provided in the substrate processing apparatus, introducing a processing gas into the processing chamber to maintain the processing chamber at a constant pressure, supplying an RF power to the discharge electrode to form an electric field and at the same time a magnetic field, and thus causing a magnetron discharge in the processing chamber to excite and break down the processing gas, the MMT apparatus can subject the substrate to different types of plasma processing such as diffusion processing by oxidizing or nitriding the surface of the substrate, forming a thin film on the substrate surface and etching the substrate surface.

The substrate processing apparatus is provided with a processing furnace 202 for plasma processing of a wafer 200 as a substrate made of silicon. The processing furnace 202 includes a processing container 203 made of a first material, a susceptor 217 installed in the processing container 203 and serving as a substrate stage on which the wafer 200 serving as the substrate is placed, a heater 217h installed in the susceptor 217 and serving as a heating part heating the wafer 200, a gas inlet part 203a installed in the processing container 203, a gas supply pipe 234 made of a second material and connected to the gas inlet part 203a with an O-ring 203b serving as a sealing member interposed therebetween to supply a processing gas to an inside of the processing chamber 201, a gas exhaust line exhausting a gas of the inside of the processing chamber 203, and a plasma generating mechanism generating plasma in the processing chamber 203. Also, the substrate processing apparatus includes a controller 121 as a control part controlling the gas supply line, the exhaust line, the plasma generating mechanism and the heater 217h, respectively.

(Processing Container)

As shown in FIG. 1, the processing container 203 provided in the processing furnace 202 includes an integrally molded dome (belljar)-shaped upper side container 210 as a first container, and a bowl-shape lower side container 211 as a second container. As the upper side container 210 covers the top of the lower side container 211, the processing container 203 having the processing chamber 201 therein is configured. The upper side container 210 is formed, for example, from aluminum oxide or from quartz or another non-metal material as a first material, and the lower side container 211 is formed, for example, from aluminum.

At a lower center of the processing chamber 201, the susceptor 217 as a substrate stage on which the wafer 200 is placed is disposed. The susceptor 217 is formed, for example, from aluminum nitride, ceramics, or quartz. In particular, in the case of requiring a material property resistant to plasma, quartz is preferred. When the susceptor 217 is made of quartz, generation of particles due to an etching by plasma can be prevented.

Inside the susceptor 217, the heater 217h as a heating part is integrally embedded. The heater 217h is configured to heat the wafer 200 which is placed on the susceptor 217. By supplying electric power to the heater 217h, the heater 217h is configured to elevate the temperature of the wafer 200 to a desired temperature.

The susceptor 217 is electrically insulated from the lower side container 211. Inside the susceptor 217, a second electrode (not shown in FIG. 1) as an electrode varying impedance is installed. This second electrode is grounded via an impedance variation mechanism 274. The impedance varying unit 274 is configured from a coil or a variable condenser, and the electric potential of the wafer 200 can be controlled via the second electrode (not shown) and the susceptor 217 by controlling the number of coil patterns or the capacitance value of the variable condenser.

In the susceptor 217, a susceptor elevator 268 for lifting or lowering the susceptor 217 is installed. In the susceptor 217, through holes 217a are formed. At a lower side of the lower side container 211, wafer push-up pins 266 pushing-up the wafer 200 are installed at least by the number corresponding to the number of the through holes 217a. The wafer push-up pins 266, when the susceptor 217 has been lowered by the susceptor elevator, are disposed so as to pierce the through holes 217a in the state where the wafer push-up pins 266 are not in contact with the susceptor 217.

In the sidewall of the lower side container 211, a gate valve 244 as a sluice valve is installed. When the gate valve 244 is opened, the wafer 200 is loaded in or unloaded from the processing chamber 201 by a carrying unit (not shown in drawing). When the gate valve 244 is closed, the processing chamber 201 is sealed air-tight.

At an upper side of the processing chamber 203 (upper side container 210), for example, a tubular gas inlet part 203a as a thermal radiation attenuator is installed. That is, the gas inlet part 203a is installed on a line connecting the heater 217h and the O-ring 203b. The gas inlet part 203a is formed, for example, from aluminum nitride, ceramics or quartz. In particular, in the case of requiring a material property resistant to plasma, quartz is preferred. When the susceptor 217 is made of quartz, generation of particles due to an etching by plasma can be prevented. At a downstream end of the gas inlet part 203a, a gas inlet (opening) 238 is formed. A gas supply pipe 234 to be described later is connected to an upstream end of the gas inlet part 203a with the O-ring 203b as a sealing member being disposed therebetween. By such a configuration, the gas inlet part 203a shields and attenuates the thermal radiation directed toward the O-ring 203b from the heater 217h, so that it becomes possible to prevent the O-ring 203b from being heated. In the case where the gas inlet part 203a is made of quartz, a distance between the O-ring 203b and the gas inlet 238, i.e., a distance of the gas inlet part 203a in the height direction is defined as a distance where the radiant heat directed toward the O-ring 203b from the heater 217h is attenuated. By attenuating the thermal radiation, the temperature of the O-ring 203b can be maintained at a temperature which is not deteriorated.

(Gas Supply Line)

As above-described, the gas supply pipe 234 supplying a processing gas to the inside of the processing container 203 (inside of the processing chamber 201) is connected to the gas inlet 238 with the O-ring 203b being disposed therebetween.

An oxygen gas supply pipe 232a supplying O₂ gas as a processing gas, a hydrogen gas supply pipe 232b supplying H₂ gas as a processing gas, and an inert gas supply pipe 232c supplying N₂ gas as an inert gas meet at and are connected to the upstream side of the gas supply pipe 234.

An oxygen gas supply source 250a, a mass flow controller 251a as a flow rate control unit, and a valve 252a as an on-ff valve are connected to the oxygen gas supply pipe 232a, sequentially from the upstream side. A hydrogen gas supply source 250b, a mass flow controller 251b as a flow rate control unit, and a valve 252b as an on-ff valve are connected to the hydrogen gas supply pipe 232b, sequentially from the upstream side. An inert gas supply source 250c, a mass flow controller 251c as a flow rate control unit, and a valve 252c as an on-ff valve are connected to the oxygen gas supply pipe 232c, sequentially from the upstream side.

A gas supply line is configured mainly by the gas supply pipe 234, the oxygen gas supply pipe 232a, the hydrogen gas supply pipe 232b, the inert gas supply pipe 232c, the oxygen gas supply source 250a, the hydrogen gas supply source 250b, the inert gas supply source 250c, the mass flow controllers 251a-251c, and the valves 252a-252c. The gas supply pipe 234, the oxygen gas supply pipe 232a, the hydrogen gas supply pipe 232b, and the inert gas supply pipe 232c are made of a second material, for example, quartz, aluminum oxide, or metal material such as SUS.

By opening the valves 252a-252c and the mass flow controllers 251a-251c controlling the flow rate, O₂ gas, H₂ gas, and N₂ gas can be supplied to the inside of the processing chamber 201 via a buffer chamber 236 disposed therebetween.

(Gas Exhaust Line)

At a lower side of a sidewall of the lower side container 211, a gas exhaust port 235 is installed. A gas exhaust pipe 231 is connected to the gas exhaust port 235. An automatic pressure controller (APC) 242 as a pressure regulator, a valve 243b as an on-off valve, and a vacuum pump 246 as an exhaust device are connected to the gas exhaust pipe 231, sequentially from the upstream side. Typically, a gas exhaust line is configured by the gas exhaust pipe 231, the APC 242, the valve 243b, and the vacuum pump 246. By operating the vacuum pump 246 and opening the valve 243b, it is possible to exhaust the inside of the processing chamber 201. Also, by controlling an open degree of the APC 242, a pressure value of the inside of the processing chamber 201 can be controlled.

(Plasma Generating Mechanism)

A cylindrical electrode 215 as a first electrode is installed around the outer periphery of the processing container 203 (the upper side container 210) so as to surround a plasma generating region 224. The cylindrical electrode 215 is formed in a tubular shape, e.g., a cylindrical shape. A high-frequency power source 273 generating a high-frequency power via a matching device 272 for performing an impedance matching is connected to the cylindrical electrode 215.

Upper and lower magnets 216a and 216b are respectively equipped at upper and lower sides of the outer surface of the cylindrical electrode 215. The upper and lower magnets 216a and 216b are respectively configured by permanent magnets formed in a tubular shape, e.g., a ring shape. The upper and lower magnets 216a and 216b have magnetic poles at both ends (i.e., the internal peripheral ends and the external peripheral ends) along the radial direction of the processing chamber 201. The magnetic poles of the upper and lower magnets 216a and 216b are inversely polarized. That is, the magnetic poles on the internal periphery are heteropolar, thereby forming a line of magnetic force in the axial direction of the cylinder along the internal peripheral surface of the cylindrical electrode 215.

A plasma generating mechanism is constituted mainly by the cylindrical electrode 215, the matching box 272, the high-frequency power source 273, the upper magnet 216a, and the lower magnet 216b. After a mixed gas of O₂ gas and H₂ gas as a processing gas is introduced into the processing chamber 201, the high-frequency power is supplied to the cylindrical electrode 215 to form an electric field and at the same time to form a magnetic field by using the upper electrode 216a and the lower electrode 216b, so that magnetron discharge plasma is generated in the processing chamber 201. At this time, the above-described electric field and magnetic field allow the emitted electrons to perform a cycloid movement, increasing the generation rate of ions due to plasma to allow generation of high-density plasma having long-life span.

Meanwhile, a shielding plate 223 is installed around the periphery of the cylindrical electrode 215 and the upper and lower magnets 216a and 216b to effectively shield the electric field and the magnetic field so that the electric field and the magnetic field formed by the cylindrical electrode 215 and the upper and lower magnets 216a and 216b do not adversely affect the external environment, other processing furnaces, or other such devices.

(Controller)

A controller 121 as a controller is configured to control the APC 242, the valve 243b, and the vacuum pump 246 through a signal line A; to control the susceptor elevator 268 through a signal line B; to control the gate valve 244 through a signal line C; to control the matching device 272 and the high-frequency power source 273 through a signal line D; to control the mass flow controllers 251a-251c and the valves 252a-252c through a signal line E; and to control the heater embedded in the susceptor or the impedance varying unit 274 through another signal line (not shown).

(2) Method of Manufacturing Semiconductor Device

Continuously, a method of manufacturing a semiconductor device relevant to an embodiment of the present invention performed by the substrate processing apparatus will be described. In the following description, the operations of the components constituting the substrate processing apparatus are controlled by the controller 121.

(Wafer Loading Process)

First of all, the susceptor 217 is lowered to a wafer loading position, and the wafer push-up pins 266 pass through the through holes 217a in the susceptor 217. As a result, the wafer push-up pins 266 protrude to just a specified height from a surface of the susceptor 217.

Continuously, the gate valve 244 opens and the wafer 200 is loaded in the processing chamber 201 by a carrying unit (not shown). As a result, the wafer 200 is horizontally supported on the wafer push-up pins 266 protruding from the surface of the susceptor 217.

After the wafer 200 is loaded in the processing chamber 201, the carrying unit retracts to the outside of the processing chamber 201, the gate valve 244 is closed, and the inside of the processing chamber 200 is sealed air-tight. The susceptor 217 is lifted by the susceptor elevator 268. As a result, the wafer 200 is disposed on the surface of the susceptor 217. Thereafter, the wafer 200 is lifted to a specified position for processing.

Meanwhile, in order to load the wafer in the processing chamber 201, it is preferable that while the inside of the processing chamber 201 is exhausted by the gas exhaust line, N₂ gas as an inert gas is supplied to the inside of the processing chamber 201 from the gas supply line to fill the inside of the processing chamber 201 with N₂ gas and at the same time to reduce oxygen concentration. That is, it is preferable to open the valve 252c and supply N₂ gas to the inside of the processing chamber 201 via the buffer chamber 237 while exhausting the inside of the processing chamber 201 by operating the vacuum pump 246 to open the valve 243b.

(Process of Raising Temperature of Wafer)

Continuously, power is supplied to the heater 217h embedded in the susceptor 217 to heat the wafer 200 to a specified temperature. At this time, the thermal radiation from the heater 217h is radiated upwardly from the lower side of the inside of the processing chamber 201. However, as above-described, the gas inlet part 203a relevant to the current embodiment is installed on a line connecting the heater 217h and the O-ring 203b. So the thermal radiation directed toward the O-ring 203b from the heater 217h is shielded and attenuated by the gas inlet part 203a to prevent the temperature of the O-ring 203b from being raised.

(Process of Introducing Processing Gas)

Continuously, the valve 252c is closed and the valves 252a, 252b are opened to introduce a processing gas, which is a mixed gas of O₂ gas and H₂ gas, into the inside of the processing chamber 201 via the buffer chamber 237. At this time, the open degrees of the mass flow controllers 251a, 251b are respectively controlled so that the flow rate of O₂ gas included in the processing gas and the flow rate of H₂ gas included in the processing gas are specific flow rates. Also, the open degree of the APC 242 is controlled so that the pressure within the processing chamber 201 after the processing gas is supplied, is maintained at a specific pressure.

(Process of Generating Plasma of Processing Gas)

After the introduction of the processing gas starts, the high-frequency power is applied to the cylindrical electrode 215 via the matching device 272 from the high-frequency power source 273 to generate magnetron discharge plasma in the processing chamber 201 (in a plasma generation area 224 above the wafer 200). That is, the processing gas is made to a plasma state by a plasma generation part. Meanwhile, the applied power is maintained at an output level of 800 W or less. At this time, the impedance varying unit 274 controls the impedance in advance to a desired impedance value.

By generating plasma as above-described, the processing gas (the mixing gas of O₂ gas and H₂ gas) introduced into the processing chamber 201 is activated. A sidewall of a gate insulating film is exposed to the processing gas activated by plasma and thus thermally oxidized. A thermal oxide film is formed on a surface of the wafer 200. Meanwhile, by only adjusting the flow rate of H₂ gas in the mixing gas, a selective oxidation, e.g., which oxidizes only the silicon surface while preventing oxidation of a metal surface on the wafer 200, becomes possible.

Thereafter, if a specified processing time elapses, the application of the power from the high-frequency power source 273 is stopped and the generation of plasma in the processing chamber 201 is stopped. The amount of thermal oxidation is defined by the flow rate of O2 gas, the flow rate of H2 gas, the pressure within the processing chamber 201, the temperature of the wafer 200, the amount of power supplied from the high-frequency power source 273, and the supply time.

(Exhaust Process in Processing Chamber)

If the generation of plasma in the processing chamber is stopped, the valves 252a, 252b are closed, the supply of the processing gas to the inside of the processing chamber is stopped, and the inside of the processing chamber 201 is exhausted. At this time, the valve 252c is opened to supply N₂ gas to the inside of the processing chamber 201, accelerating the exhaust of the processing gas or reaction product remaining in the processing chamber 201. Thereafter, the open degree of the APC 242 is adjusted to adjust the pressure within the processing chamber 201 to a pressure which is the same as that of a vacuum lock chamber (where the wafer 200 is unloaded, not shown) adjacent to the processing chamber 201.

(Process of Unloading Wafer)

Once the pressure within the processing chamber 201 returns to the atmospheric pressure, the susceptor 217 is lowered to an unloading position of the wafer 200 to support the wafer 200 on the wafer push-up pins 266. Thereafter, the gate valve 244 is opened to unload the wafer 200 to the outside of the processing chamber 201 by using the carrying unit (not shown), completing the manufacturing of the semiconductor device relevant to the current embodiment.

(3) Effects Relevant to the Current Embodiment

According to the current embodiment, one or more of the following effects can be attained.

According to the current embodiment, the gas inlet part 203a, which is formed in a cylindrical shape as a thermal radiation attenuating part, is installed at an upper side of the processing container 203 (the upper side container 210). The gas inlet part 203a is installed on a line connecting the heater 217h and the O-ring 203b. Therefore, the thermal radiation direction toward the O-ring 203b from the heater 217h is shielded by the gas inlet part 203a, so that the temperature of the O-ring can be prevented from being raised. Also, contamination of the inside of the processing chamber 201 or the wafer 200 due to melting of the O-ring 203b can be prevented.

Also, according to the current embodiment, since the gas inlet part 203a is installed in a line connecting the heater 217h and the O-ring 203b, the O-ring 203b is rarely exposed to the magnetron discharge plasma generated in the inside of the processing chamber 201. Further, it is possible to prevent air-tightness of the processing chamber 203 from being lowered due to the deterioration of the O-ring 203b

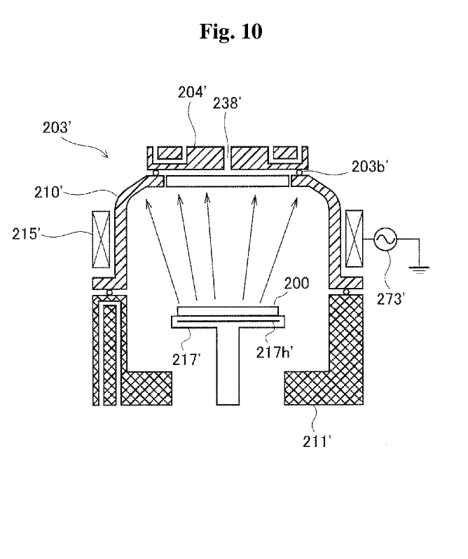

For reference, a constitutional example of a conventional substrate processing apparatus will be described with reference to FIG. 10.

In the conventional substrate processing apparatus, an upper side container 210′ constituting a processing container 203′ has an opened upper portion. The opening of the upper side container 210′ is configured so as to be closed by a cover 204′ having a gas inlet 238′ with an O-ring 203b′ interposed therebetween. In a susceptor 217′ installed at a lower center of the inside of the processing container 203′ (the inside of a processing chamber 201′), a heater 217h′ heating a wafer 200′ placed on the susceptor 217′ is integrally embedded. In the conventional substrate processing apparatus, since a member shielding thermal radiation is not installed between the heater 217h′ and the O-ring 203b′, the O-ring 203b′ is easily subject to the thermal radiation from the heater 217′ and is sometimes deteriorated by temperature rising. Also, the O-ring 203b′ may be melted by heat to contaminate the inside of the processing chamber 201′ or the wafer 200′. Further, the O-ring 203b is exposed to magnetron discharge plasma and thus deteriorated, so that the air-tightness of the inside of the processing container 203 may be lowered. To solve these limitations, in the present embodiment, since the gas inlet part 203a is installed on a line connecting the heater 217h and the O-ring 203b, it is possible to solve the above-described objects.

### Second Embodiment of the Present Invention

Hereinafter, a second embodiment of the present invention will be described with reference to FIG. 3. FIG. 3 is a schematic view illustrating that a thermal radiation directed toward an O-ring 203b is shielded and attenuated by a gas inlet 203a serving as a thermal radiation attenuator, relevant to a second embodiment of the present invention.

The current embodiment differs from the above-described embodiment in that a cylindrical gas inlet 203a is made of white glass (white quartz, opaque quartz) having high attenuation efficiency of a thermal radiation and plasma-resistant property. The other configurations of the current embodiment are the same as those of the above-described embodiment.

In the current embodiment, since the cylindrical gas inlet 203a is made of white glass, the thermal radiation directed toward the O-ring 203b from a heater 217h is further attenuated assuredly, thereby further preventing the temperature of the O-ring 203b from being raised. In addition, it is possible to further prevent air-tightness in a processing container 203 from being lowered due to the deterioration of the O-ring 203b, and also possible to further prevent an inside of the processing chamber 201 or a substrate from being contaminated due to the melting of the O-ring 203b.

### Third Embodiment of the Present Invention

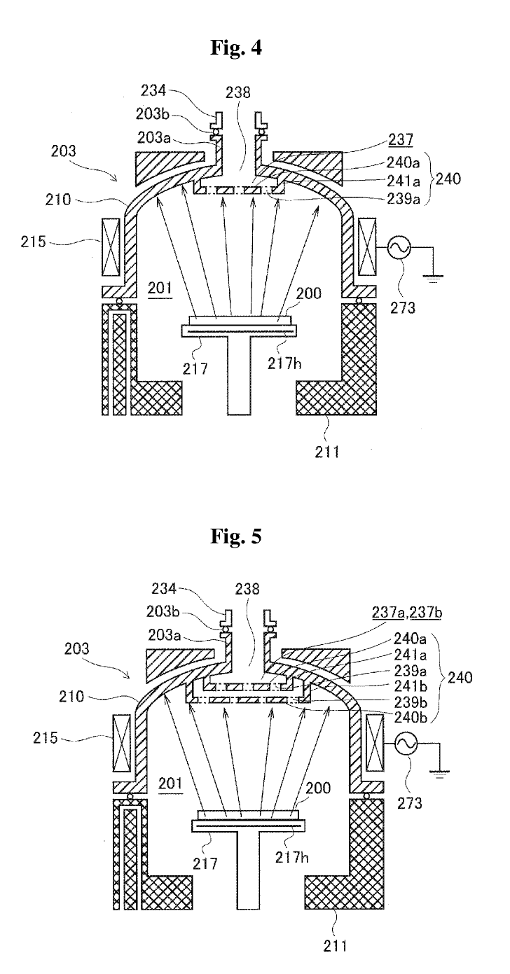

Hereinafter, a third embodiment of the present invention will be described with reference to FIG. 4. FIG. 4 is a schematic view illustrating that a thermal radiation toward an O-ring 203b is shielded by a gas inlet 203a according to a third embodiment of the present invention.

The current embodiment differs from the first and second embodiments in that a substrate processing apparatus includes a gas dispersing part (shower head) 240 configured to disperse a processing gas supplied from a gas supply pipe 234 serving as a thermal radiation attenuator. The gas dispersing part 240 is installed on a line connecting a heater 217h and the O-ring 203b. The other configurations of the current embodiment are the same as those of the above-described embodiment.

Specifically, the gas dispersing part 240 is provided with the shower plate 240a horizontally supported. For example, the shower plate 240a is configured by a disk plate. A cylindrical sidewall 241a is installed on an outer periphery of the shower plate 240a. An upper end of the sidewall 241a is in airtight contact with an inner wall of an upper side container 210 so as to surround an outer periphery of the gas inlet 238. A plurality of gas injection holes 239a are dispersively installed in the shower plate 240a.

A space between the shower plate 240a and the upper side container 210 serves as a buffer chamber 237 with the gas inlet 203a disposed therebetween, which allows the processing gas supplied from the gas supply pipe 234 to be dispersed.

According to the current embodiment, one or more of the following effects can be attained.

According to the current embodiment, the gas inlet 203a and the gas dispersing part 240 serving as thermal radiation attenuators are installed on a line connecting the heater 217h and the O-ring 203b. As a result, the thermal radiation directed toward the O-ring 203b from the heater 217h is further attenuated assuredly, thereby further preventing the temperature of the O-ring 203b from being raised. In addition, it is possible to further prevent air-tightness in a processing container 203 from being lowered due to the deterioration of the O-ring 203b, and also possible to further prevent an inside of the processing chamber 201 or a substrate from being contaminated due to the melting of the O-ring 203b. In the case where the shower plate 240a and the sidewall 241a are made of white glass, the thermal radiation directed toward the O-ring 203b from the heater 217h is further attenuated surely.

Also, according to the current embodiment, since the gas inlet 203a and the gas dispersing part 240 serving as thermal radiation attenuators are installed on a line connecting the heater 217h and the O-ring 203b, the O-ring 203b is rarely exposed to magnetron discharge plasma generated in the processing chamber 201. In addition, it is possible to prevent air-tightness in a processing container 203 from being lowered due to the deterioration of the O-ring 203b, and also possible to prevent an inside of the processing chamber 201 or a substrate from being contaminated due to the melting of the O-ring 203b.

Furthermore, according to the current embodiment, the processing gas supplied from the gas supply pipe 234 is dispersed by the gas dispersing part 240 serving as the thermal radiation attenuator. This allows the processing gas to be uniformly supplied to a wafer 200, enhancing the in-plane uniformity in processing a substrate.

### Fourth Embodiment of the Present Invention

Hereinafter, a fourth embodiment of the present invention will be described with reference to FIG. 5. FIG. 5 is a schematic view illustrating that a thermal radiation toward an O-ring 203b is shielded by a gas inlet 203a and a gas dispersing part 240, relevant to a fourth embodiment of the present invention.

In the gas dispersing part 240 as a thermal radiation attenuator relevant to the current embodiment, shower plates each having a plurality of gas injection holes are dually installed, and the gas injection holes of one of the shower plates are arranged not to vertically overlap the gas injection holes of the other one of the shower plates vertically adjacent thereto, when viewed from a wafer stage of a susceptor 217. The other configurations of the current embodiment are the same as those of the above-described embodiment.

Specifically, the gas dispersing part 240 includes a shower plate (upper side) 240a and a shower plate (lower side) 240b which are horizontally disposed and stacked up and down. For example, each of the shower plates 240a and 240b is configured by a disk plate. The diameter of the shower plate 240b is greater than the diameter of the shower plate 240a. A sidewall 241a is installed on an outer periphery of the shower plate 240a. An upper end of the sidewall 241a is in airtight contact with an inner wall of an upper side container 210 so as to surround an outer periphery of the gas inlet 238. A sidewall 241b is installed on an outer periphery of the shower plate 240b. An upper end of the sidewall 241b is in airtight contact with an inner wall of the upper side container 210 so as to surround an outer periphery of the sidewall 241a. A plurality of gas injection holes 239a are dispersively installed in the shower plate 240a. A plurality of gas injection holes 239b are dispersively installed in the shower plate 240b. A space between the shower plate 240a and the upper side container 210 serves as a buffer chamber 237a with the shower plate 240a disposed therebetween, which allows the processing gas supplied from the gas supply pipe 234 to be dispersed. A space between the shower plate 240a and the shower plate 240b serves as a buffer chamber 237b with the shower plate 240a disposed therebetween, which functions to further disperse the supplied processing gas.

The shower plates 240a and 240b are configured such that the gas injection holes 239a and the gas injection holes 239b do not overlap vertically. That is, the shower plates 240a and 240b are configured such that the O-ring 203b is shielded by at least one of the shower plate (upper side) 240a and the shower plate (lower side) 240b, when the O-ring 203b is viewed from the heater 217h.

According to the current embodiment, one or more of the following effects can be attained.

According to the current embodiment, the gas inlet 203a and the gas dispersing part 240 serving as thermal radiation attenuators are installed on a line connecting the heater 217h and the O-ring 203b. As a result, the thermal radiation directed toward the O-ring 203b from the heater 217h is further attenuated assuredly, thereby further preventing the temperature of the O-ring 203b from being raised. In addition, it is possible to further prevent air-tightness in a processing container 203 from being lowered due to the deterioration of the O-ring 203b.

Also, the contamination of an inside of a processing chamber 201 or a substrate, which may be caused by the melting of the O-ring 203b, can be further prevented. In the case where the shower plate 240a and the sidewall 241a are made of white glass, the thermal radiation toward the O-ring 203b from the heater 217h is further attenuated assuredly.

According to the current embodiment, the gas injection holes 239a and the gas injection holes 239b are arranged not to overlap vertically. That is, the shower plates 240a and 240b are configured such that the O-ring 203b is shielded by at least one of the shower plate (upper side) 240a and the shower plate (lower side) 240b, when the O-ring 203b is viewed from the heater 217h. This enables the thermal radiation directed toward the O-ring 203b from a heater 217h to be further attenuated assuredly, thereby further preventing the temperature of the O-ring 203b from being raised. In addition, it is possible to further prevent air-tightness in a processing container 203 from being lowered due to the deterioration of the O-ring 203b, and also possible to further prevent an inside of the processing chamber 201 or a substrate from being contaminated due to the melting of the O-ring 203b.

Furthermore, according to the current embodiment, the gas inlet 203a and the gas dispersing part 240 serving as thermal radiation attenuators are installed on a line connecting the heater 217h and the O-ring 203b, and therefore the O-ring 203b is rarely exposed to magnetron discharge plasma generated in the processing chamber 201. This makes it possible to prevent air-tightness in a processing container 203 from being lowered due to the deterioration of the O-ring 203b, and also prevent an inside of the processing chamber 201 or a substrate from being contaminated due to the melting of the O-ring 203b.

Moreover, according to the current embodiment, the processing gas supplied from the gas supply pipe 234 is dispersed by the gas dispersing part 240 serving as the thermal radiation attenuator. This allows the processing gas to be uniformly supplied to a wafer 200, enhancing the in-plane uniformity in processing a substrate.

### Fifth Embodiment of the Present Invention

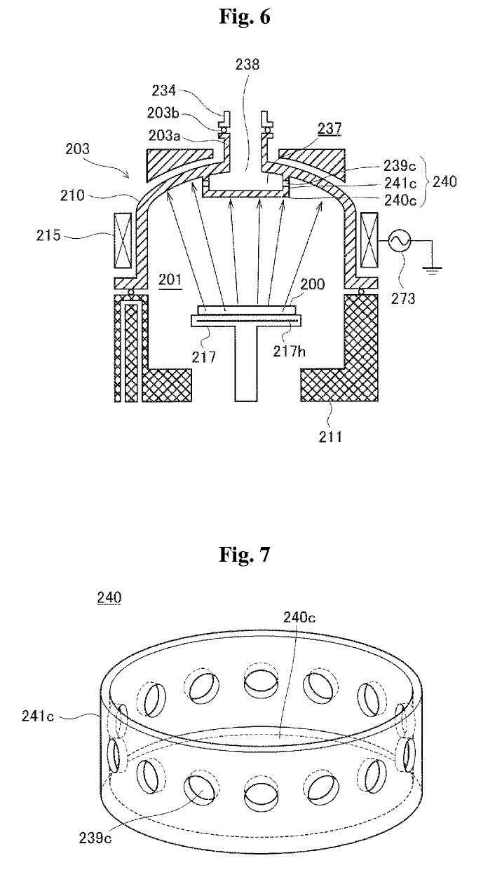

Hereinafter, a fifth embodiment of the present invention will be described with reference to FIGS. 6 and 7. FIG. 6 is a schematic view illustrating that a thermal radiation toward an O-ring 203b is shielded by a gas dispersing part 240 serving as a thermal radiation attenuator, relevant to a fifth embodiment of the present invention. FIG. 7 is a perspective view of a gas inlet, relevant to the fifth embodiment of the present invention.

The gas dispersing part 240 relevant to the current embodiment is provided with a cylindrical part of which a top is opened and a bottom is closed. In a sidewall 241c, i.e., a side surface of the cylindrical part, a plurality of gas injection holes 239c are dispersively installed. The gas injection hole is not installed in a bottom plate 240c, the bottom of the cylindrical part. That is, the bottom plate 240c is a hole-free plate. The other configurations of the current embodiment are the same as those of the above-described embodiment.

According to the current embodiment, one or more of the following effects can be attained.

According to the current embodiment, the gas inlet 203a and the gas dispersing part 240 serving as thermal radiation attenuators are installed on a line connecting the heater 217h and the O-ring 203b. As a result, the thermal radiation directed toward the O-ring 203b from the heater 217h is further attenuated assuredly, thereby further preventing the temperature of the O-ring 203b from being raised. In addition, it is possible to further prevent air-tightness in a processing container 203 from being lowered due to the deterioration of the O-ring 203b. In addition, the contamination of an inside of a processing chamber 201 or a substrate, which may be caused by the melting of the O-ring 203b, can be further prevented. In the case where the bottom plate 240c and the sidewall 241a are made of white glass, the thermal radiation toward the O-ring 203b from the heater 217h is further attenuated assuredly.

Furthermore, according to the current embodiment, the gas injection holes 239c are installed in the sidewall 241c but not installed in the bottom plate 240c of the cylindrical part. The thermal radiation directed toward the O-ring 203b from a heater 217h is further attenuated by the bottom plate 240c assuredly, thereby further preventing the temperature of the O-ring 203b from being raised. In addition, it is possible to further prevent air-tightness in a processing container 203 from being lowered due to the deterioration of the O-ring 203b, and also possible to further prevent an inside of the processing chamber 201 or a substrate from being contaminated due to the melting of the O-ring 203b.

Moreover, according to the current embodiment, the gas inlet 203a and the gas dispersing part 240 serving as thermal radiation attenuators are installed on a line connecting the heater 217h and the O-ring 203b, and therefore the O-ring 203b is rarely exposed to magnetron discharge plasma generated in the processing chamber 201. This makes it possible to prevent air-tightness in a processing container 203 from being lowered due to the deterioration of the O-ring 203b, and also prevent an inside of the processing chamber 201 or a substrate from being contaminated due to the melting of the O-ring 203b.

### Another Embodiment of the Present Invention

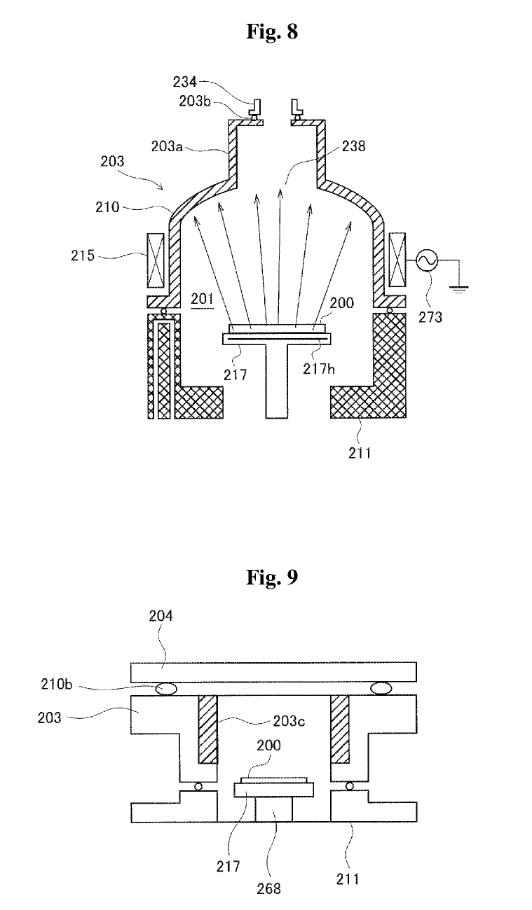

Although, in the previous embodiments, the temperature increase of the O-ring 203b is prevented by installing the gas inlet 203a and the gas dispersing part 240 serving as thermal radiation attenuators on a line connecting the heater 217h and the O-ring 203b, the present invention is not limited thereto. In the current embodiment, as shown in FIG. 8, a thermal radiation incident on the O-ring 203b is reduced by separating position of the O-ring serving as a sealing member from the heater 217h. Also, in the current embodiment, by arranging the O-ring 203b in this way, the O-ring 203b is rarely exposed to magnetron discharge plasma generated in the processing chamber 201 so that the deterioration of the O-ring is prevented.

### Still Another Embodiment of the Present Invention

Although the upper side container 210 relevant to the previous embodiments is an integrally molded dome (belljar)-shaped upper side container, the present invention is not limited thereto. For example, as shown in FIG. 9, the upper side container 210 may have an opening at the top thereof, and the opening of the upper side container 210 may be closed by a cover 204 with the O-ring 210b as a sealing member disposed therebetween. In the case of increasing the size or diameter of the integrally molded upper side container 210 in order to process a large-sized wafer 200 having a diameter exceeding 450 mm, the processing container 203 does not endure an external pressure but is susceptible to collapse. According to the current embodiment, the resistance of the processing container 203 against the external pressure can be improved by preparing the cover 204 separately.

Also, in the current embodiment, a thermal radiation suppressor 203c, which is made of white quartz and configured to shield a thermal radiation toward an inner wall of the upper side container 210, is installed on a line connecting the heater 217h and the O-ring 210b. Accordingly, the thermal radiation directed toward the O-ring 210b from the heater 217h is shielded by the thermal radiation attenuator 203c as the thermal radiation attenuator. Thus, the temperature increase of the O-ring 203b is prevented, making it possible to prevent air-tightness in a processing container 203 from being lowered due to the deterioration of the O-ring 203b. In addition, the contamination of an inside of a processing chamber 201 or a substrate resulting from the melting of the O-ring 203b can be prevented.

### Yet Another Embodiment of the Present Invention

Although, in the previous embodiments, it is illustrated that an oxidation treatment is performed on the surface of the wafer 200 to oxidize the surface of the wafer 200 by using plasma, the present invention is not limited thereto. That is, the present invention is not limited to the oxidation treatment, and thus suitably applicable even to the case of nitriding the surface of the wafer 200, forming a thin film on the wafer and etching the wafer 200. Also, the present invention is not limited to the substrate-processing using plasma, and is very suitably applicable to the substrate-processing even in the case of not using plasma.

Although the embodiments of the present invention are described in detail, the present invention is not limited to the above-described embodiments, and various changes in form and details may be made in the embodiments without departing from the spirit and scope of the present invention.

In the substrate processing apparatus and the method of manufacturing a semiconductor device according to the present invention, it becomes possible to prevent a sealing member from being deteriorated due to a thermal radiation from a heater.

(Supplement Note)

The present invention also includes the following embodiments.

(Supplement Note 1)

According to a preferred embodiment of the present invention, there is provided a substrate processing apparatus comprising: a processing container; a substrate stage installed in the processing container, on which a substrate is placed; a heater installed in the substrate stage and configured to heat the substrate; a thermal radiation attenuator adjacent to the processing container; and a gas supply pipe connected to a gas inlet part with a sealing member interposed therebetween and configured to supply a processing gas to an inside of the processing container, wherein the thermal radiation attenuator is installed on a line connecting the heater and the sealing member.

(Supplement Note 2)

Preferably, the thermal radiation attenuator may be made of white glass.

(Supplement Note 3)

According to another preferred embodiment of the present invention, there is provided a substrate processing apparatus comprising: a processing container; a substrate stage installed in the processing container, on which a substrate is placed; a heater installed in the substrate stage and configured to heat the substrate; a gas inlet part installed in the processing container; a gas supply pipe connected to the gas inlet part with a sealing member interposed therebetween and configured to supply a processing gas to an inside of the processing container; and a gas dispersing part configured to disperse the processing gas supplied from the gas supply pipe, wherein the gas dispersing part is installed on a line connecting the heater and the sealing member.

(Supplement Note 4)

Preferably, the gas dispersing part may include a first shower plate having a first group of holes adjacent to a gas supply hole, and a second shower plate installed between the first shower plate and the substrate stage and having a second group of holes, and the first group of holes and the second group of holes may be configured so as not to overlap each other as viewed from a substrate supporting surface.

(Supplement Note 5)

Preferably, the gas dispersing part may have a side surface having a hole and a bottom surface which is a hole-free surface.

(Supplement Note 6)

According to further another preferred embodiment of the present invention, there is provided a method of manufacturing a semiconductor device comprising: loading a substrate to a processing container and placing the substrate on a substrate stage; heating the substrate by using a heater installed in the substrate stage; processing the substrate by supplying a processing gas to the processing container via a thermal radiation attenuator, which is connected to a processing gas supply pipe with a sealing member disposed therebetween and is installed on a line the substrate stage and the sealing member; and unloading the substrate from a processing chamber.

(Supplement Note 7)

According to still another preferred embodiment of the present invention, there is provided a substrate processing apparatus comprising: a processing container; a substrate stage installed in the processing container, on which a substrate is placed; a heater installed in the substrate stage and configured to heat the substrate; a gas inlet part installed in the processing container; and a gas supply pipe connected to the gas inlet part with a sealing member interposed therebetween and configured to supply a processing gas to an inside of the processing container, wherein the gas inlet part is installed on a line connecting the heater and the sealing member.

(Supplement Note 8)

According to even another preferred embodiment of the present invention, there is provided a substrate processing apparatus comprising: a substrate stage on which a substrate is placed and which has a heater therein; a gas supply pipe configured to supply a processing gas and made of a first material; a gas inlet part connected to the gas supply pipe with a sealing member disposed therebetween; and a processing chamber in which the substrate stage is included and which is made of a second material, wherein the gas inlet part is installed on a line connecting the heater and the sealing member.

(Supplement Note 9)

According to yet another preferred embodiment of the present invention, there is provided a substrate processing apparatus comprising: a processing container; a substrate stage installed in the processing container, on which a substrate is placed; a heater installed in the substrate stage and configured to heat the substrate; a gas inlet part installed in the processing container; a gas supply pipe connected to the gas inlet part with a sealing member interposed therebetween and configured to supply a processing gas to an inside of the processing container; and a gas dispersing part configured to disperse the processing gas supplied from the gas supply pipe, wherein the gas dispersing part is installed on a line connecting the heater and the sealing member.

(Supplement Note 10)

According to another preferred embodiment of the present invention, there is provided a substrate processing apparatus comprising: a substrate stage on which a substrate is placed and which has a heater therein; a gas supply pipe configured to supply a processing gas and made of a first material; a gas inlet part connected to the gas supply pipe with a sealing member disposed therebetween; a gas dispersing part configured to disperse the processing gas supplied from the gas supply pipe; and a processing chamber in which the substrate stage is included and made of a second material, wherein the gas dispersing part is installed on a line connecting the heater and the sealing member.

(Supplement Note 11)

Preferably, the sealing member may be configured by an O-ring.

(Supplement Note 12)

Preferably, the gas inlet part may be made of white glass attenuating a thermal radiation directed toward the sealing member from the heater.

(Supplement Note 13)

Preferably, the gas dispersing part may comprise a shower plate in which a plurality of gas injection holes are dispersively installed.

(Supplement Note 14)

Preferably, the gas dispersing part may have a cylindrical part of which a top is opened and a bottom is closed, and the cylindrical part may have a sidewall having a plurality of gas injection holes dispersively installed, and a bottom plate not having a gas injection hole.

(Supplement Note 15)

Preferably, the sealing member may be installed at a position spaced apart by a specified distance from the heater so as to reduce a thermal radiation irradiated from the heater to the sealing member.

(Supplement Note 16)

Preferably, a thermal radiation preventing part configured to reduce a thermal radiation irradiated to the sealing member is installed on a line connecting the heater and the sealing member at an inner wall of the processing container.

What is claimed is:

1. A substrate processing apparatus comprising:
a processing container;
a substrate stage installed in the processing container, on which a substrate is placed;
a heater installed in the substrate stage and configured to heat the substrate;
a thermal radiation attenuator adjacent to the processing container; and
a gas supply pipe connected to a gas inlet part with a sealing member interposed therebetween and configured to supply a processing gas to an inside of the processing container,
wherein the thermal radiation attenuator is installed on a line connecting the heater and the sealing member.

2. The substrate processing apparatus of claim 1, wherein the thermal radiation attenuator is made of white glass.

3. A method of manufacturing a semiconductor device comprising:
loading a substrate to a processing container and placing the substrate on a substrate stage;
heating the substrate by using a heater installed in the substrate stage;
processing the substrate by supplying a processing gas to the processing container via a thermal radiation attenuator, which is connected to a processing gas supply pipe with a sealing member disposed therebetween and is installed on a line the substrate stage and the sealing member; and
unloading the substrate from a processing chamber.
